(19) United States
(12) Patent Application Publication
(10) Pub. No.: US 2022/0216361 A1
(43) Pub. Date: Jul. 7, 2022

(54) REWORK DEVICE AND REWORK METHOD

(71) Applicant: Henkel AG & Co. KGaA, Duesseldorf (DE)

(72) Inventors: JiaYun Zhang, Beijing (CN); Yong Liu, Shanghai (CN); JiBing Fu, Shanghai (CN); Lin Zhao, Shanghai (CN); JunXi Wu, Shanghai (CN); Qi Yue, Shanghai (CN); KeFan Ni, Shanghai (CN)

(21) Appl. No.: 17/455,025

(22) Filed: Nov. 16, 2021

Related U.S. Application Data
(63) Continuation of application No. PCT/CN2019/087755, filed on May 21, 2019.

(51) Int. Cl. H01L 31/18; B65G 37/00; H01L 31/05

(52) U.S. Cl. CPC H01L 31/1876; F27B 17/0016; H01L 31/0504; B65G 37/005

(57) ABSTRACT

The present disclosure provides a rework device and a rework method useful in reworking a shingle cell module. The rework device includes a first supporting component, a second supporting component and a heating component disposed between the first supporting component and the second supporting component and being flush with the second supporting component. The first supporting component is inclined at an angle with respect to the heating component. This type of rework device and rework method has the advantages of simple structure, low cost and convenient operation.

### FIELD OF THE INVENTION

The present disclosure relates to the technical field of reworking of a shingle cell module, and more particularly to a rework device and a rework method.

### BACKGROUND OF THE INVENTION

Due to the complicated process of overlaying shingle cells to manufacture a shingle cell module, the shingle cell equipment does not have a high yield. A shingle cell module typically includes 34 to 68 pieces of cells. If one piece of cell has an issue of overlaying or is cracked, the full shingle cell module cannot be used any more. Therefore, reworking is important for manufacturing of the shingle cell module so that the total cost can be reduced.

The current rework method mainly includes:
1) Use a thin metal blade (about 100 um thick) or a narrow metal wire (50-100 um) to cut the electrically conductive adhesive (ECA) and separate the issued cell. The disadvantages of this method include: it is difficult to operate because the blade and wire are very soft; it is difficult to apply this method with the auto-operation; it is difficult to rework the shingle cell module with high modulus ECA; the adjacent cells may be cracked during the reworking.
2) Heat the issued cell at very high temperature (500° C. -600° C.) to break the ECA, or heat the whole shingle cell module and separate the issued cell, or heat the ECA area and then use external tools to separate the issued cell.

For the shingle cell module with low modulus ECA, the reworking could be done under room temperature by the tools mentioned above. However, for the shingle cell module with high modulus ECA, the rework process requires high temperature to break the ECA, which will increase the difficulty of reworking.

Therefore, there is a need to improve existing rework device and rework method.

### SUMMARY OF THE INVENTION

The object of the present disclosure is to improve the existing rework device and rework method, and to provide a new type of rework device and rework method. This type of rework device and rework method has the advantages of simple structure, low cost and convenient operation.

According to one aspect of the present disclosure, a rework device for a shingle cell module is provided. The rework device comprises: a first supporting component; a second supporting component; and a heating component disposed between the first supporting component and the second supporting component and being flush with the second supporting component. The first supporting component is inclined at an angle with respect to the heating component.

In some embodiments of the present disclosure, the first supporting component is adapted to be inclined at various angles with respect to the heating component.

In some embodiments of the present disclosure, the heating component is made of iron, stainless steel or aluminum.

In some embodiments of the present disclosure, the angle is greater than 0 degree and less than or equal to 50 degree.

According to another aspect of the present disclosure, a rework device for a shingle cell module is provided. The rework device comprises: a first supporting component and a second supporting component; and a heating component disposed between the first supporting component and the second supporting component. The heating component is adapted to heat and rotate a target cell.

In some embodiments of the present disclosure, the first supporting component and the second supporting component are in form of conveyor belts

In some embodiments of the present disclosure, the rework device further comprises a rotating component. The heating component is adapted to heat the target cell without rotating the target cell, and the rotating component is adapted to rotate the target cell.

In some embodiments of the present disclosure, the heating component is an infrared heating oven, and the rotating component is adapted to absorb the target cell and rotate the target cell therewith.

In some embodiments of the present disclosure, the heating component is adapted to absorb the target cell and rotate the target cell therewith.

In some embodiments of the present disclosure, the heating component comprises a plurality of holes for absorbing the target cell through vacuum absorption.

In some embodiments of the present disclosure, the heating component is made of iron, stainless steel or aluminum.

According to another aspect of the present disclosure, a rework method for a shingle cell module is provided. The shingle cell module comprises a plurality of cells connected in sequence. The rework method comprises: providing a first supporting component, a second supporting component and a heating component disposed between the first supporting component and the second supporting component and being flush with the second supporting component, the first supporting component being inclined at an angle with respect to the heating component; placing the shingle cell module on the first supporting component and the second supporting component such that one edge of a target cell is on the heating component; using the heating component to heat the one edge of the target cell; placing the other edge of a target cell on the heating component; and using the heating component to heat the other edge of the target cell.

According to another aspect of the present disclosure, a rework method for a shingle cell module is provided. The shingle cell module comprises a plurality of cells connected in sequence. The rework method comprises: providing a first supporting component and a second supporting component, and a heating component disposed between the first supporting component and the second supporting component; placing the shingle cell module on the first supporting component and the second supporting component such that a target cell is on the heating component; using the heating component to heat both edges of the target cell; and using the heating component to rotate the target cell.

In some embodiments of the present disclosure, the first supporting component and the second supporting component are in form of conveyor belts, and the first supporting component and the second supporting component move the shingle cell module to a position where the target cell is on the heating component.

In some embodiments of the present disclosure, the rework method further comprises a step of using the heating component to absorb the target cell before the step of using the heating component to heat both edges of the target cell.

In some embodiments of the present disclosure, the heating component absorbs the target cell through vacuum absorption via a plurality of holes on the heating component.

The technical effects of the rework device and rework method according to the present disclosure are as follows:
1) For the shingle cell module with high modulus ECA, the rework process requires lower working temperature to separate the issued cell, and the process is easier, safer and more energy saving.
2) The process could be handled by one person or automatically
3) The efficiency and success ratio is higher.
4) There is no hard damage on the cell surface.
5) It could be applied to other typical ECA in shingle field.

The above advantages and other advantages and features will become apparent from the following detailed description of the preferred embodiments.

### BRIEF DESCRIPTION OF THE DRAWINGS

In order to better understand the present disclosure, the present disclosure will be specifically described by the specific embodiments and the accompanying drawings.

FIG. 1 is a side view of the rework device according to an exemplary embodiment of the present disclosure.

FIG. 2 is a perspective view of the heat component of the rework device according to another exemplary embodiment of the present disclosure.

FIG. 3A is a side view of the rework device according to another exemplary embodiment of the present disclosure prior to rotation of 7′; and FIG. 3B is a side view of the rework device of FIG. 3A after 7′ rotates around its rotation axis 19′ to separate the target cell 13′ from the shingle cell module 9′.

### DETAILED DESCRIPTION OF THE INVENTION

As will be understood by one of ordinary skill in the art, the various features of the embodiments shown and described with respect to any one of the figures can be combined with the features shown in one or more other figures to produce other embodiments that are not explicitly shown or described. The combination of features shown provides a representative embodiment for a typical application. However, various combinations and modifications of the features are possible in accordance with the teachings of the present disclosure for a particular application or implementation.

In the present specification, the words “upper”, “lower”, “left”, “right” and the like are used for convenience only, and are not restrictive.

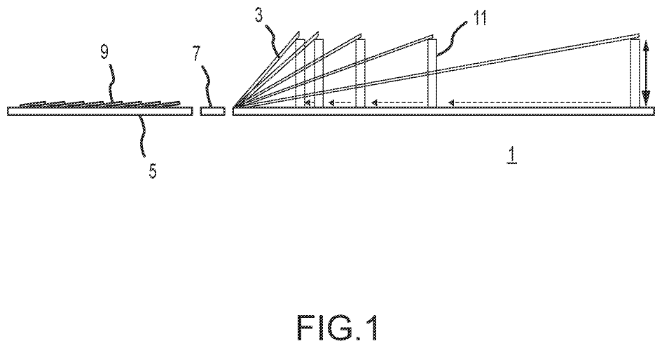

FIG. 1 is a side view of the rework device according to an exemplary embodiment of the present disclosure. As shown in FIG. 1, in the illustrated embodiment, the rework device 1 mainly includes a first supporting component 3, a second supporting component 5, and a heating component 7 disposed between the first supporting component 3 and the second supporting component 5. In the illustrated embodiment, the first supporting component 3 and the second supporting component 5 are in form of supporting plates. The first supporting component 3 and the second supporting component 5 are suitable for supporting a shingle cell module 9. It should be understood that in some embodiments, the second supporting component can be omitted, with only the first supporting component being disposed adjacent to the heating component.

The shingle cell module 9 typically includes 34 to 68 pieces of cells connected in sequence. The cells are connected in sequence by overlaying the edges of adjacent cells with electrically conductive adhesive (ECA). The width of the ECA area is usually less than 1 mm.

As shown in FIG. 1, in the illustrated embodiment, the heating component 7 is in form of a heating plate. The heat component 7 is suitable for heating the issued cell, i.e. the target cell, especially for heating either edge of the target cell so that the target cell can be removed from the shingle cell module 9. The heating component 7 can be made of iron, stainless steel or aluminum or any other suitable heat conductive material.

As shown in FIG. 1, in the illustrated embodiment, the first supporting component 3 is inclined at an angle with respect to the heating component 7. Specifically, the end of the first supporting component 3 away from the heating component 7 is supported by a block 11. With the block 11 being provided at different locations, the first supporting component 3 is inclined at various angles with respect to the heating component 7. It is also possible for the block 11 to be provided at a fixed location such that the first supporting component 3 is inclined with respect to the second supporting component 5 at a fixed angle. The first supporting component 3 is inclined at an angle greater than zero degree, which means the first supporting component 3 is not on the same plane with the heating component 7. In some embodiments, the angle may be less than or equal to fifty degree.

It should be understood that angle between the first supporting component and the heating component can be achieved with another configuration. For example, the first supporting component may be supported by a pivotable bracket. It should also be understood, in some embodiments, the first supporting component and the second supporting component may be of other forms. For example, the first supporting component may be in form of a wedged block and the second supporting component may be in form of a table top. In such case, the shingle cell module is supported on the surface of the table top and the wedge block.

As shown in FIG. 1, in the illustrated embodiment, the surface of the heating component 7 is flush with the surface of the second supporting component 5. Therefore, the shingle cell module 9 can be supported smoothly on the second supporting component 5.

It is described now the process of reworking with the above rework device 1. First, the shingle cell module 9 is placed on the first supporting component 3, the heating component 7 and the second supporting component 5. As the first supporting component 3 is inclined at an angle with respect to the heating component 7, a part of the shingle cell module 9 supported on the first supporting component 3 is inclined at such an angle with respect to another part of the shingle cell module 9 supported on the second supporting component 5. One edge of the target cell (a first edge) is supported on the heating component 7. The ECA area at this edge of the target cell is heated by the heating component 7 at a certain temperature for a certain period of time. Then the target cell is separated along this edge. In order to separate the target cell along the other edge (a second edge), that edge of the target cell is then placed on the heating component 7. The ECA area at that edge of the target cell is heated by the heating component 7 at a certain temperature for a certain period of time. Then the target cell is entirely separated. After that, a new cell may be overlaid with the remaining two shingle cell strings so that the shingle cell module is reworked.

According to an exemplary embodiment of the present disclosure, a rework method for a shingle cell module is provided. The shingle cell module includes a plurality of cells connected in sequence. The rework method includes steps of:
1) providing a first supporting component 3 and a heating component 7 disposed adjacent to the first supporting component 3, the first supporting component 3 being inclined at an angle with respect to the heating component 7;
2) placing the shingle cell module 9 on the first supporting component 3 such that one edge of a target cell is on the heating component 7;
3) using the heating component 7 to heat the one edge of the target cell;
4) placing the other edge of a target cell on the heating component 7; and
5) using the heating component 7 to heat the other edge of the target cell.

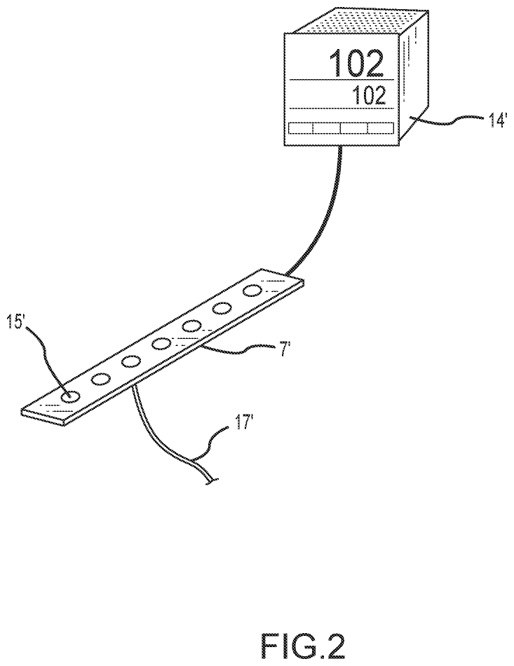

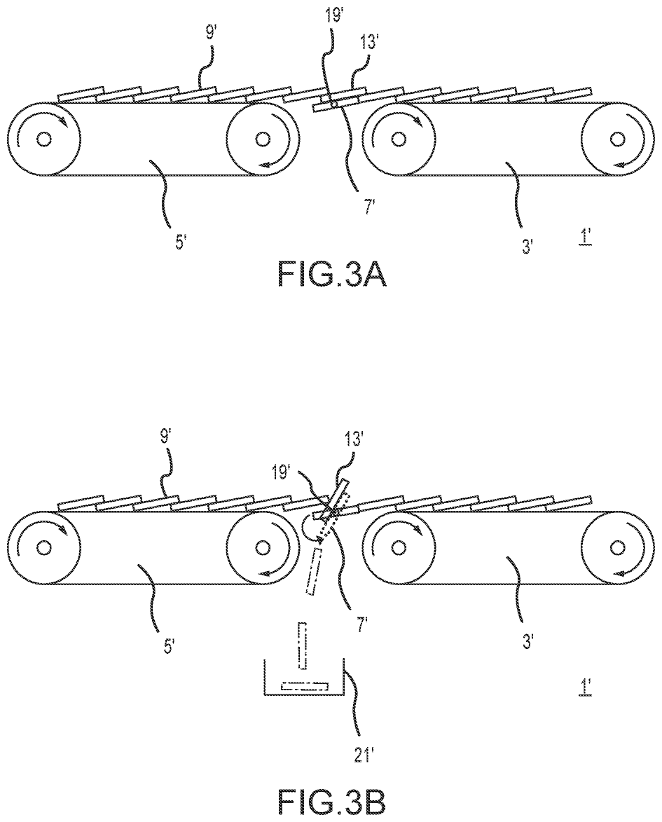

FIG. 2 is a perspective view of the heat component of the rework device according to another exemplary embodiment of the present disclosure. FIG. 3A and FIG. 3B show a side view of the rework device according to another exemplary embodiment of the present disclosure. As shown in FIGS. 2, 3A and 3B, in the illustrated embodiment, the rework device 1′ mainly includes a first supporting component 3′, a second supporting component 5′, and a heating component 7′ disposed between the first supporting component 3′ and the second supporting component 5′. In the illustrated embodiment, the first supporting component 3′ and the second supporting component 5′ are in form of conveyor belts. The first supporting component 3′ and the second supporting component 5′ are suitable for supporting a shingle cell module 9′. The first supporting component 3′ and the second supporting component 5′ can move the shingle cell module 9′ to a position where the target cell 13′ is on the heating component 7′.

It should be understood that the first supporting component and the second supporting component may be of other forms. For example, the first supporting component and the second supporting component may be in form of supporting plates. In such case, the shingle cell module can be moved by external tools such as robot arms to a position where the target cell is on the heating component.

As shown in FIGS. 2, 3A and 3B, in the illustrated embodiment, the heating component 7′ is in form of a heating plate. The heat component 7′ is suitable for heating the target cell 13′, especially for heating both edges of the target cell 13′ so that the target cell 13′ can be removed from the shingle cell module 9′. It should be understood that, due to heat transferring, the heating component can heat both edges of the target cell by means of contacting and heating the middle part of the target cell. The heating component 7′ can be made of iron, stainless steel or aluminum or any other suitable heat conductive material. As shown in FIG. 2, the heating component 7′ may be connected to a temperature controller 14′ so as to control the temperature of the heating component 7′.

As shown in FIGS. 2, 3A and 3B, in the illustrated embodiment, the heating component 7′ is capable of heating and rotating the target cell 13′. Specifically, the heating component 7′ can absorb the target cell 13′ and rotate the target cell 13′ therewith. As shown in FIG. 2, in the illustrated embodiment, the heating component 7′ includes several holes 15′. The heating component 7′ may be connected to a vacuum absorption device (not shown) through a vacuum absorption tube 17′. The vacuum absorption device allows the heating component 7′ to absorb the target cell 13′ via the vacuum absorption tube 17′ and the holes 15′ on the heating component 7′. It should be understood that the heating component can absorb the target cell by other means.

As shown in FIGS. 3A and 3B, in the illustrated embodiment, the heating component 7′ has a rotation axis 19′ at its center. The heating component 7′ can rotate around the rotation axis 19′. As the heating component 7′ can absorb the target cell 13′, when the heating component 7′ starts to rotate, it exerts force onto both edges of the target cell 13′ to separate it from the shingle cell module 9′ and rotates the target cell 13′ therewith.

It should be understood that it is possible for the heating component to be capable of heating the target cell without rotating the target cell. In such case, the rework device may include a rotating component which is capable of rotating the target cell. In some embodiments, the heating component is an infrared heating oven. The infrared heating oven may be disposed above the target cell and heat the target cell by infrared radiation. The rotating component may be a rotating plate with several holes. The rotating plate may absorb and rotate the target cell in the same way as the heating component mentioned above.

It is described now the process of reworking with the above rework device. First, the shingle cell module 9′ is placed on the first supporting component 3′, the heating component 7′ and the second supporting component 5′. The first supporting component 3′ and the second supporting component 5′ move the shingle cell module 9′ to a position where the target cell 13′ is on the heating component 7′. The heating component 7′ then absorbs the target cell 13′ via the vacuum absorption tube 17′ and the holes 15′ on the heating component 7′. After that, the target cell 13′ is heated by the heating component 7′. Especially, the ECA areas on both edges of the target cell 13′ are heated by the heating component 7′ at a certain temperature for a certain period of time. As shown in the lower drawing FIG. 3B, the heating component 7′ then rotates around its rotation axis 19′ to separate the target cell 13′ from the shingle cell module 9′ and rotates the separated target cell 13′ therewith. The heating component 7′ then releases the target cell 13′ and the target cell 13′ drops to the receiving basket 21′ below the heating component 7′.

According to an exemplary embodiment of the present disclosure, it is provided a rework method for a shingle cell module. The shingle cell module includes several cells connected in sequence. The rework method includes steps of:
1) providing a first supporting component 3′ and a second supporting component 5′, and a heating component 7′ disposed between the first supporting component 3′ and the second supporting component 5′;
2) placing the shingle cell module 9′ on the first supporting component 3′ and the second supporting component 5′ such that a target cell 13′ is on the heating component 7′;
3) using the heating component 7′ to heat both edges of the target cell 13′; and
4) using the heating component 7′ to rotate the target cell 13′.

In some embodiments, the first supporting component 3′ and the second supporting component 5′ are in form of conveyor belts, and the first supporting component 3′ and the second supporting component 5′ move the shingle cell module 9′ to a position where the target cell 13′ is on the heating component 7′.

In some embodiments, the rework method includes a step of using the heating component 7′ to absorb the target cell 13′ before the step of using the heating component 7′ to heat both edges of the target cell 13′. Specifically, the heating component 7′ absorbs the target cell 13′ through vacuum absorption via a plurality of holes 15′ on the heating component 7′.

From the above description, those skilled in the art shall be aware of the solutions and advantages of the rework device and the rework method according to the present disclosure. For instance, the rework device of the present disclosure has simple structure and low cost. For the shingle cell module with high modulus ECA, the rework process requires lower working temperature to separate the issued cell, and the process is easier, safer and more energy saving. The process could be handled by one person or automatically. The efficiency and success ratio is higher. There is no hard damage on the cell surface. It could be applied to other typical ECA in shingle field.

A person skilled in the art will readily recognize that various changes and modifications can be made therein without departing from the true spirit and scope of the invention as defined by the following claims.

What is claimed is:

1. A rework device for a shingle cell module, the rework device comprising:
a first supporting component;
a second supporting component; and
a heating component disposed between the first supporting component and the second supporting component and being flush with the second supporting component;
wherein the first supporting component is inclined at an angle with respect to the heating component.

2. The rework device of claim 1, wherein the first supporting component is adapted to be inclined at various angles with respect to the heating component.

3. The rework device of claim 1, wherein the angle is greater than 0 degree and less than or equal to 50 degree.

4. A rework device for a shingle cell module, the rework device comprising:
a first supporting component and a second supporting component; and
a heating component disposed between the first supporting component and the second supporting component;
wherein the heating component is adapted to heat and rotate a target cell.

5. The rework device of claim 4, wherein the first supporting component and the second supporting component are in form of conveyor belts.

6. The rework device of claim 4 further comprising a rotating component, wherein the heating component is adapted to heat the target cell without rotating the target cell, and the rotating component is adapted to rotate the target cell.

7. The rework device of claim 6, wherein the heating component is an infrared heating oven, and the rotating component is adapted to absorb the target cell and rotate the target cell therewith.

8. The rework device of claim 4, wherein the heating component is adapted to absorb the target cell and rotate the target cell therewith.

9. The rework device of claim 4, wherein the heating component comprises a plurality of holes for absorbing the target cell through vacuum absorption.

10. A rework method for a shingle cell module, the shingle cell module comprising a plurality of cells connected in sequence, the rework method comprising:
providing a first supporting component, a second supporting component and a heating component disposed between the first supporting component and the second supporting component and being flush with the second supporting component, the first supporting component being inclined at an angle with respect to the heating component;
placing the shingle cell module on the first supporting component and the second supporting component such that a first edge of a target cell is on the heating component;
heating the first edge of the target cell with the heating component;
placing a second edge of the target cell on the heating component; and
heating the second edge of the target cell with the heating component.

11. A rework method for a shingle cell module, the shingle cell module comprising a plurality of cells connected in sequence, the rework method comprising:
providing a first supporting component and a second supporting component, and a heating component disposed between the first supporting component and the second supporting component;
placing the shingle cell module on the first supporting component and the second supporting component such that a target cell of the shingle cell module is on the heating component;
heating both edges of the target cell with the heating component; and
using the heating component to rotate the target cell.

12. The rework method of claim 10, wherein the first supporting component and the second supporting component are in form of conveyor belts, and the first supporting component and the second supporting component move the shingle cell module to a position where the target cell is on the heating component.

13. The rework method of claim 10 further comprising a step of using the heating component to absorb the target cell before the step of using the heating component to heat both edges of the target cell.

14. The rework method of claim 13 wherein the heating component absorbs the target cell through vacuum absorption via a plurality of holes on the heating component.
